(19) United States
(12) Patent Application Publication
(10) Pub. No.: US 2009/0041936 A1
(43) Pub. Date: Feb. 12, 2009

(54) COMPOSITE REFLECTIVE BARRIER

(75) Inventors: Angelo Yializis, Tucson, AZ (US); James DiBattista, Tucson, AZ (US); Gordon Goodyear, Tucson, AZ (US)

Correspondence Address: ANTONIO R. DURANDO, 6902 N. TABLE MOUNTAIN ROAD, TUCSON, AZ, 85718-1331, US

(73) Assignee: Sigma Laboratories of Arizona, LLC., Tucson, AZ (US)

(21) Appl. No.: 12/250,083

(22) Filed: Oct. 13, 2008

Related U.S. Application Data
(63) Continuation-in-part of application No. 11/586,478, filed on Oct. 25, 2006.
Application No. 11/586,478 is a continuation-in-part of application No. 11/335,039, filed on Jan. 18, 2006.
Application No. 11/335,039 is a continuation-in-part of application No. 10/335,373, filed on Dec. 31, 2002, now Pat. No. 6,981,322.
Application No. 10/335,373 is a continuation-in-part of application No. 11/589,564, filed on Oct. 30, 2006.
Application No. 11/589,564 is a division of application No. 10/830,608, filed on Apr. 23, 2004, now Pat. No. 7,157,117.
Application No. 11/589,564 is a continuation-in-part of application No. 10/465,399, filed on Jun. 19, 2003, now abandoned.
(60) Provisional application No. 60/465,719, filed on Apr. 25, 2003.
(60) Provisional application No. 60/391,864, filed on Jun. 26, 2002.

(51) Int. Cl. C23C 16/00

(52) U.S. Cl. 427/250

(57) ABSTRACT

A coated, low-emissivity aluminum film is manufactured entirely in vacuum by depositing an aluminum layer over a substrate and then immediately coating the metal layer with a very thin protective polymeric layer. The thickness of this coating is selected to minimize absorption in the 3-15 micron wavelength. In vacuum, the metal layer is coated substantially in the absence of moisture, thereby preventing the formation of hydrated oxides that promote corrosion. The aluminum layer is preferably also passivated by in-line exposure to a plasma gas containing an oxygen-bearing component. A leveling polymeric layer may also be deposited between relatively rough substrates and the aluminum layer in order to improve the reflectivity of the resulting structures.

### RELATED APPLICATIONS

This application is a continuation-in-part application of U.S. Ser. No. 11/566,478, filed Oct. 25, 2006, which was a CIP of U.S. Ser. No. 11/335,039, filed Jan. 18, 2006, which in turn was a CIP of U.S. Ser. No. 10/355,373, filed Jan. 31, 2003. This application is also a continuation-in-part application of U.S. Ser. No. 11/599,564, filed Oct. 30, 2006, which vas a divisional of U.S. Ser. No. 10/830,608, filed Apr. 23, 2004, based on U.S. Provisional No. 60/465,719, filed Apr. 25, 2003, and was also a CIP of U.S. Ser. No. 10/465,399, filed Jun. 19, 2003, based on U.S. Provisional No. 60/391,864, filed Jun. 26, 2002.

### BACKGROUND OF THE INVENTION

1. Field of the Invention

This invention is related in general to reflective barriers used for insulation purposes. In particular, the invention relates to a method of in-vacuum production of low-emissivity films with a protective coating of a thickness designed to minimize absorption at the infrared wavelengths of interest. In addition, the invention makes it possible to increase the durability and efficiency of the reflective film through passivation and leveling during the deposition process.

2. Description of the Related Art

Radiant-barrier materials (also commonly referred to in the industry as low-emissivity barriers) consist of a reflective, metallic foil, most often aluminum, coated with a protective layer, typically a polymeric film. These barriers are designed to reflect heat and involve different structures for different heat-reflection applications. For example, low-emissivity glass includes a multilayer coating on the glass surface designed to reflect solar heat while still transmitting substantially all visible light. Such coatings typically consist of a high refractive-index metal oxide layer sputtered on one or both sides of the glass. Other radiant barriers are designed for reflecting heat into or away from the human body and are incorporated into blankets, gloves, boots, etc. as flexible structures of polymer films metallized or laminated to aluminum foil.

Radiant barriers are also used to reflect heat into or away from housing structures and packaging containers. Many of these barriers consist of aluminum foils in combination with polymer films, paper and other fibrous materials. Aluminum foil laminated on a substrate provides an economic solution for achieving good reflection without resorting to materials like gold or silver or complex multilayer optical filters.

Aluminum foils used in radiant barriers are usually referred to in the art as “low-emissivity” foils, though it is understood that “high-reflectivity” would be more correct in view of the fact that the insulating performance of these multilayer structures results from their ability to reflect incident radiation energy. Both terms will be used interchangeably herein. It is also noted that the term “film,” as contrasted to “foil,” is used in the industry to refer to vacuum-deposited metal layers, as opposed to bulk metal layers laminated onto a substrate. Therefore, these terms will be used in the same manner herein.

Metallic radiant barriers require protection from abrasion and corrosion, which is achieved by coating or laminating the metal foil (normally aluminum) with a protective layer such as a polymer film. However, when deposited with traditional deposition techniques, such as lacquer coating, gravure and roll coating, these protective layers are substantially thicker than necessary to protect the aluminum foil. As a result, the coating absorbs some of the radiation impinging on the barrier, which increases the effective emissivity of the combined coating/aluminum layer, thereby reducing the efficiency of the radiant barrier. This fact has been recognized as an unavoidable drawback of protective coatings, but no attempt has been made to correct it or diminish its impact.

Another problem with aluminum foils lies in the loss of reflectivity that aluminum-foil structures experience over time. Through exposure to air, a protective layer of Al₂O₃ is normally formed on the aluminum surface. However, over time, exposure to moisture also produces a hydrated aluminum oxide, Al₂O₃.(H₂O)ₙ, which is structurally inferior to Al₂O₃ and results in corrosion of the aluminum layer. This tendency of aluminum to form hydrated oxides is a problem in many metallized film applications because the corrosion leads to a rapid deterioration of the reflectivity and barrier properties of the metallized layer, which are critical for the industries in which these products are used (such as reflectivity for insulation and impermeability to oxygen and moisture in packaging). Thus, it is clear that improvements in the stability of the metal layer would produce another desirable advance in the quality of these multilayer barriers.

Yet another problem of particular interest to the building industry is the tendency of the traditional aluminum foil used in radiant barriers to permit propagation of fire. These foils consist of a layer of bulk aluminum laminated on a backing of some sort, normally paper or a similar support material. A typical application involves the use of such a reflective aluminum foil in combination with an insulating barrier, such as a layer of wood, foam, or other conventional insulating material. The aluminum foil is either bonded or placed adjacent to the insulating material to reflect radiation (primarily IR wavelengths), thereby increasing the efficiency of the insulation. As such, the metallic layer acts as a barrier to radiation.

As mentioned, these low-emissivity foils tend to sustain and propagate combustion. Because of the thickness of the aluminum foil, the aluminum layer tends to retain its integrity under fire and to allow a flame started along the backing of the foil to spread over adjacent combustible areas. Flame retardants are used to reduce the danger, but they add to the cost and often lose their efficacy over time.

An alternative approach has been to replace the foil with an aluminum film produced by depositing a thin layer of aluminum in vacuum over a substrate, such as PET, and then coating the aluminum with conventional lacquer or gravure techniques to provide a protective layer. The use of these films has been found to improve the flame propagation properties of the resulting low-emissivity structure. Because the vacuum-deposited aluminum layer in such films is much thinner than in foils (in the order of angstroms as compared to microns), it appears that, when on fire, the multilayer structure crumbles and separates from adjacent combustible material. Thus, the fire tends to be arrested and contained within the source area.

This self-extinguishing characteristic of aluminum films represents a very desirable property for low-emissivity applications in the building industry. However, the conventional processes used to coat these films with a protective layer (mostly gravure and roll coating) necessarily result in the entrapment of atmospheric moisture between the aluminum and the coating layers. As these metal films corrode due to the formation of hydrated oxides, they become less shiny and their ability to reflect incident radiation is correspondingly degraded, as described above.

This invention is directed at providing a solution to these remaining problems in the manufacture of radiant barriers. The invention is based on a useful discovery about the character of light absorption of polymer films as a function of wavelength and utilizes thin-film deposition technology developed for the functionalization of porous materials, described in co-owned Ser. No. 10,830,608, and passivation technology of aluminum nanoflakes and films, described in co-owned Ser. No. 11/335,039 and Ser. No. 11/536,479, all of which are hereby incorporated by reference. The invention is described primarily with reference to aluminum because it is the preferred metal for the applications covered by this disclosure, but it can be practiced in similar manner with other metals, such as tin, copper, zinc, silver, and with alloys and metal oxides such as ITO (indium-tin oxide).

### BRIEF SUMMARY OF THE INVENTION

In view of the foregoing, this invention is directed at a general approach for manufacturing a much improved low-emissivity metallized film, preferably an aluminized film. According to one aspect of the invention, the thickness of the protective layer is tailored to minimize absorption of undesirable electromagnetic wavelengths. This can be achieved using the process control flexibility afforded by vacuum deposition technology which, according to another aspect of the invention, also permits the implementation of a passivation technique designed to prevent corrosion and the corresponding degradation in the reflectivity characteristics of the film. The process is equally advantageous for all multilayer metallized structures. The building industry categorizes low-emissivity structures as reflective insulation and radiant barriers, but the distinction is not relevant to this invention; therefore, all insulation applications are intended to be covered by this disclosure.

The low-emissivity film for insulation applications is preferably manufactured, according to the invention, entirely in vacuum by depositing a metal layer over a substrate and then immediately coating the metal layer with a flash-evaporated protective layer. As mentioned, the thickness of the protective layer is selected so as to optimize reflection (i.e., minimise absorption) at the infrared wavelengths where the protective layer exhibits maximum absorption. This is based on the fact that the materials typically used to coat the metal layer exhibit an absorption spectrum that is substantially the same and low at all wavelengths except for peaks within the infrared range that vary as a function of the nature of the material and the material's thickness. Therefore, for a given protective material, the efficiency of the radiant barrier can be optimized by measuring experimentally the minimum thickness required for reducing absorption to a desired degree and then depositing the protective layer at that thickness under the controlled conditions afforded by in-vacuum deposition. Flash-evaporation is a process that permits the deposition of the very thin layers required to minimize absorption. Therefore, flash-evaporation is preferred, though it is recognized that any vacuum evaporation process that allows fine control of the thickness of deposition may be used to practice the invention.

According to another aspect of the invention, the metal layer, in particular aluminum and its alloys, is preferably exposed to a passivating agent in line during manufacture of the metallized film, under conditions that promote uniform passivation without undesirable secondary effects. The heart of this aspect of the invention lies in the utilization of oxygen (molecular, ionized, or atomic) to passivate the aluminum layers in vacuum immediately after deposition.

The passivation step is performed in line during the process of deposition of the aluminum layer onto the substrate. Oxygen or a plasma gas containing an oxygen-bearing component (such as molecular oxygen or a molecule containing oxygen, e.g. CO₂, N₂O, etc.) is introduced into the vacuum chamber, preferably under conditions designed to promote the formation of activated oxygen, which favors rapid oxidation. Oxygen-bearing molecules such as N₂O or CO₂, when added to a conventional inert plasma gas (such as argon, helium or nitrogen), produce activated oxygen in the plasma gas with a negligible amount of molecular oxygen, which has been found to produce the desired long-term anticorrosion effect on the metallic layer.

According to yet another aspect of the invention, a leveling polymeric layer may be deposited between the substrate and the aluminum layer in order to improve the reflectivity of the structure by providing a smoother reflective surface. This additional step is particularly useful when the aluminum layer is deposited on a substrate with a relatively rough surface. The leveling layer tends to fill the gaps and produce a smoother surface for the deposition of the aluminum layer, which in turn results in a smoother and more reflective aluminum-film structure.

Various other purposes and advantages of the invention will become clear from its description in the specification that follows and from the novel features particularly pointed out in the appended claims. Therefore, the invention consists of the features hereinafter illustrated in the drawings, fully described in the detailed description of the preferred embodiments and particularly pointed out in the claims.

### BRIEF DESCRIPTION OF THE DRAWINGS

FIG. 1 is a chart of, measured reflectance versus wavelength for different coating thicknesses over an aluminum substrate illustrating the peaks and the limited bands of absorption wavelengths within the infrared range that characterize a typical protective material used to coat reflective layers of radiant barriers.

FIG. 2 is a schematic representation of a vacuum chamber adapted to metallize a substrate web and deposit a polymeric protective coating in line.

FIG. 3 is a schematic representation of the vacuum chamber of FIG. 2, further including a plasma treater and an oxygen-bearing gas source placed past the metal-evaporation stage to passivate the top side of the deposited metal layers.

FIG. 4 is a schematic representation of the same vacuum chamber of FIG. 3, further including an additional plasma treater with an oxygen source placed ahead of the metal-evaporation unit to passivate the bottom side of the deposited metal layer.

FIG. 5 is a schematic representation of the same vacuum chamber of FIG. 4, further including an additional monomer-evaporation unit and an associated radiation-curing unit placed upstream of the plasma treater to deposit a leveling layer on the substrate being treated.

### DESCRIPTION OF THE PREFERRED EMBODIMENTS OF THE INVENTION

The invention is based on several distinct improvements in the process of manufacturing multilayer structures for radiant-barrier applications, particularly for low-emissivity aluminum barrier structures. A protective layer for the reflective metallic film is formed in-line by flash evaporation and vacuum deposition immediately after the deposition of the metal layer, thereby sealing the aluminum in vacuum before any moisture is able to contact its surface. The thickness of the protective layer is selected so as to minimize absorption at the infrared wavelengths of interest, thereby maximizing the efficiency of the radiant barrier. Further, either or both sides of the aluminum layer may be treated with a passivating plasma in-line to provide immediate formation of a superficial passivating layer that prevents subsequent corrosion of the aluminum. Finally, a leveling layer may be vacuum deposited between the substrate and the metal layer to provide smoothness and increase reflectivity when a substrate with a relatively rough surface is used.

For the purposes of this disclosure, the term “gas” is intended to also include vapors. Accordingly, the term “condensation” refers to the phase change from gas to liquid (and subsequently solid) obtained upon contact of a gas (or vapor) with a surface having a temperature lower than the dew point of the gas at a given operating pressure. Such a surface may be the substrate subjected to vapor deposition, which has been either pre-chilled or is in contact with a cold drum in the vacuum chamber, or it may be the cold drum itself. “Plasma gas” means a gaseous molecule subjected to an electric field so as to produce ionized species. The term “monomer” is intended to include also oligomers and blends of monomers and/or oligomers capable of controlled evaporation in a vacuum chamber. “Flash evaporation” is the process by which a substance is evaporated (wherein evaporation is understood to include sublimation, as the case may be) substantially instantly in vacuum upon contact with a heat source, such as a hot plate or a hot atmosphere. “Oxygen-bearing” molecules and gases are intended to refer not only to molecular oxygen but also to molecules and gases that contain oxygen (for example, CO₂, N₂O, etc.).

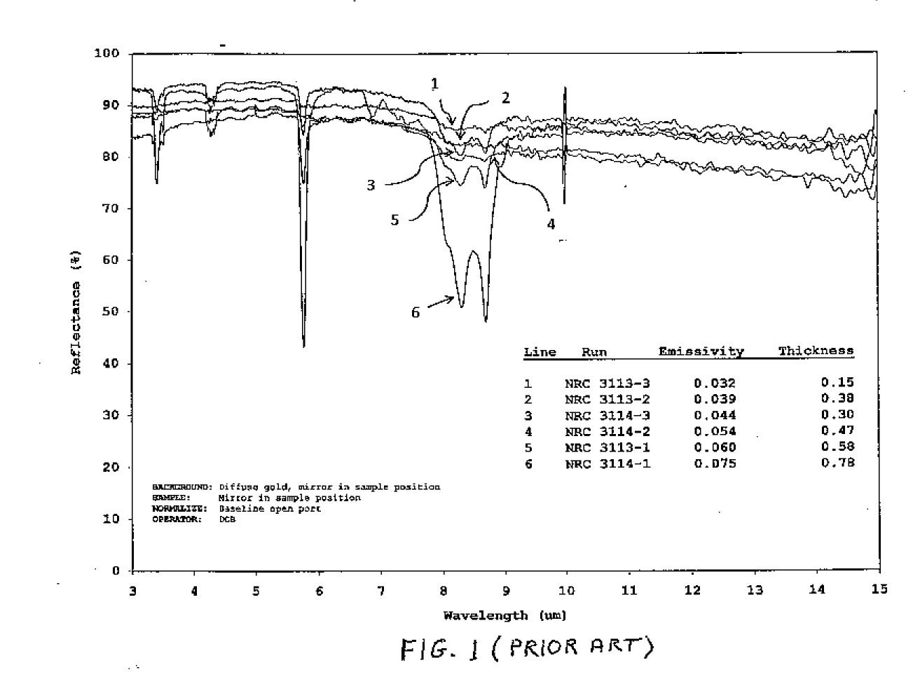

While it has been known that the protective layers used in radiant barriers absorb heat and therefore limit the efficiency of the barriers, the common attitude has been simply to try to limit the thickness of the coating to an acceptable level that also provided the required protective function. Given the limits afforded by conventional deposition methods in controlling the uniformity and thickness of deposition, no attempt has been made before to further optimize the absorption characteristics of the radiant barrier. The present invention is based in part on the fact that each coating material used to protect an otherwise substantially totally reflective substrate exhibits a characteristic absorption spectrum with multiple peaks that appear mostly in the infrared wavelength range of 3 to 15 microns. These peaks decrease to a substantially constant value for thicknesses below a certain threshold and further decrease only negligibly for thinner layers. FIG. 1 illustrates this property for six different thicknesses of a Zonyl/Hdoda material (a fluoro-acrylate/hexanediol-diacrylate) deposited over an aluminum substrate sufficiently thick to exhibit total reflectance.

Note that the plots in the figure represent reflectance measured with a Fourier Transform Infra Red (FTIR) spectrometer equipped with an integrating sphere, which, in the case of a coated reflective metallic layer reflecting substantially all the energy impinging on it, provides an indirect measure of the absorption of the coating. Therefore, as one skilled in the art would readily understand, every low point in the reflectance spectrum of the barrier corresponds to a high peak in the absorption spectrum of the protective material covering the gold substrate. The figure shows that at each measured thickness the reflectance is substantially the same and high at all wavelengths except for the ranges where the low points appear. Therefore, these low points, which correspond to peaks in the absorption spectrum, can be used as a measure of the overall absorbance of the radiant barrier as a function of the thickness of the protective layer. Because of the correspondence between absorption peaks and reflectance low points, both will be referred to herein a peaks (that is, the term will be used to refer both to positive and negative deviations from the general trend of the spectrum).

FIG. 1 shows that in the case of a Zonyl/Hdoda coating over aluminum, the peaks of the reflectance spectra increase from the 45-50% range to about 75-80% when reducing the thickness of the Zonyl/Hdoda layer from 0.78 to about 0.50 micron. Each subsequent reduction in thickness produces much smaller gains. That is, there is a thickness below which further thinning of the protective layer does not produce material gains in the reflectance of the barrier (that is, the absorption of the layer no longer decreases by any significant amount). Therefore, one objective of the invention is to deposit the protective layer at substantially that thickness, so that maximum mechanical protection is provided without sacrificing the efficiency of the radiant barrier.

Therefore, according to the invention, the protective material is tested to determine the thickness at which the peaks in the 3 to 15 micron range of wavelength falls below a predetermined acceptable value of absorption, and then the material is deposited at that thickness over the reflective layer using flash evaporation and in-vacuum deposition, a process that affords fine control over, and guarantees uniformity of, the thickness of deposition. Thus, using flash evaporation to coat an aluminum layer with a protective film, the thickness of the protective film can be minimized to the degree required to provide the necessary mechanical protection while preventing absorption of any significant amount of incident radiation. Vie found that the thickness that increases the reflectance of the barrier to at least 75 percent is optimal for manufacturing a reflective barrier that is both efficient and well protected from abrasion.

In general, we found that the absorption behavior of most coating materials correlates well with the wavelength at which absorption is measured. Specifically, we found that absorption is minimized to an acceptable level (about 75% reflectance, which corresponds substantially to the level below which absorption cannot be materially reduced in practice) if the thickness of the coating layer does not exceed about 0.50μ. Table I below illustrates this finding for four commonly used protective materials,

TABLE 1

| Emissivity | Thickness, μ | Material |
|---|---|---|
| 0.044 | 0.38 | Zonyl/HDODA |
| 0.049 | 0.39 | HDODA/CD406 |
| 0.054 | 0.47 | Zonyl/HDODA |
| 0.034 | 0.40 | 60/20/20 |

Zonyl is a fluoro-acrylate; HDODA is 1,6-hexanediol-diacrylate;
CD406 is 1,4-cyclohexane-diacrylate; and 60/20/20 is a formulation of diacrylates (60% Glycol Diacrylate, 20% Acid Ester Triacrylate, and 20% Triazin Triacrylate)

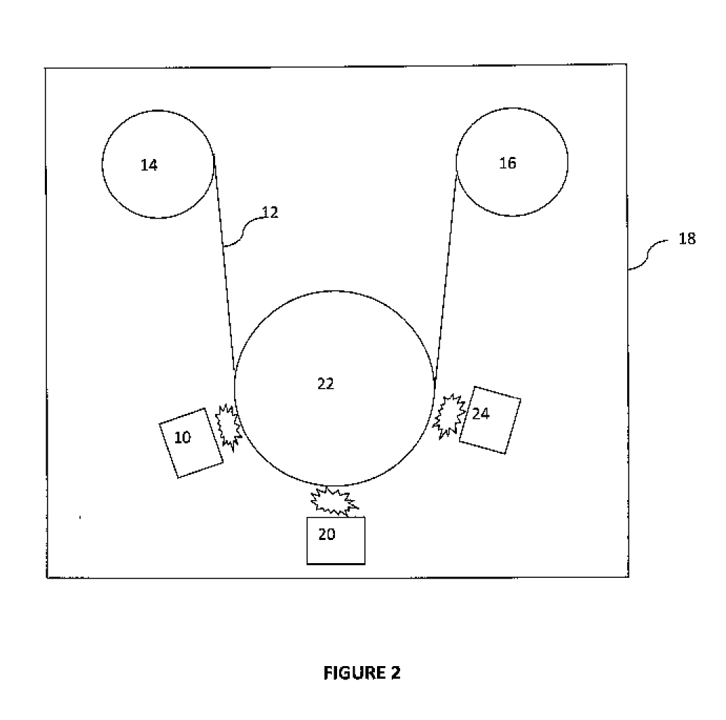

In the preferred embodiment, the invention is practiced in line during the course of manufacturing low-emissivity barriers wherein a metallic layer is deposited over a web and a protective layer, typically a polymeric layer, is flash evaporated and vacuum deposited over the metal layer in the same chamber, as illustrated in FIG. 2. As is well understood in the art, a metal-evaporation unit 10 is used to evaporate and deposit a metallic layer over a substrate web 12 spooled between a feed roller 14 and a take-up roller 16 in a conventional vacuum chamber 18. A monomer-evaporation unit 20 is used to flash-evaporate a protective material (such as an acrylate, for example) suitable to form a thin protective layer on the metal, over a cold rotating drum 22 in the vacuum chamber. A radiation-curing unit 24, typically a high-voltage electron-beam gun or a UV-light device, is used, if necessary, to cure the monomer into a thin solid film of protective material. The speed of the rotating drum 22 is controlled to produce the desired thickness for each layer of the multilayer structure.

According to the invention, the vaporised monomer is deposited at the desired thickness over the cold drum 22 in line after the deposition of the metal layer. As discussed above, conventional deposition techniques, such as lacquer coating, gravure, and roll coating, cannot be controlled to the same extent and necessarily produce thicker coatings than ideal for barrier applications. This advantage of flash evaporation was tested by depositing a protective polymeric film less than 0.5 micron on aluminum. The barrier so produced was then compared to conventionally coated aluminum-foil barriers by exposing the reflective surface of each directly to an IR source at room temperature according to ASTM Procedure E 408-71 (2002). The emissivity of each surface was then measured for a comparison of their ability to absorb heat. Table 2 below shows that the flash-evaporated layer exhibited a lower emissivity (i.e., a higher reflectivity) than the conventional roll-coated aluminum film, which demonstrates that less incident heat was retained and correspondingly less energy was conducted through the barrier,

TABLE 2
Heat Barrier Performance

| Sample Exposed to | | |
|---|---|---|
| Incident 300 Watt UV | Thickness of | Emissivity Measured |
| Light | Protective Layer | From Barrier |
| Al Film of Invention | 0.30 micron | 0.044 |
| Al Film of Invention | 0.25 micron | 0.036 |
| Al Film of Invention | 0.30 micron | 0.041 |
| Roll-Coated Foil 1 | 0.80 micron | 0.077 |
| Roll-Coated Foil 2 | 0.80 micron | 0.076 |

Another notable gain produced by the invention is the fact that flash evaporation can be carried out in-line immediately after the aluminum layer has been deposited by resistive evaporation, reactive sputtering, or other vacuum processes. As a result of this in-line operation, the aluminum surface is immediately sealed by the coating layer deposited over it, thereby preventing entrapment of moisture and the attendant subsequent formation of corrosive hydrated oxides. By so sealing the surface of the metallic layer, it was found that the resistance to corrosion is improved when compared to metal films produced by prior-art methods. In particular, a comparison of aluminum films coated with conventional atmospheric processes with the aluminum barrier of the invention showed that the former degraded rapidly under harsh test conditions while the latter remained practically unaffected. Example 1 below illustrates these results as measured by the change in optical density (and therefore also emissivity) of various test samples.

Optical density (“OD”) is defined as the logarithm of the ratio of the light incident on a sample and the light transmitted through it. Optical density is usually expressed in terms of base-ten logarithmic values that range between zero and about 1.80 (because the accuracy of measurement limits near-zero transmission readings). An 0D value of zero refers to full transmission, while an OD of 1.80 refers to transmission slightly greater than 1 percent. OD values are conventionally grouped into intervals of 0.10 OD units. Emissivity is defined as the ratio of energy radiated by a material to the energy radiated by a black body at the same temperature. Thus, a true black body would have an emissivity of one, while any real object has an emissivity smaller than one. It is a measure of the material's ability to absorb and radiate energy. Therefore, it is also used as a measure of the material's reflectivity (often emissivity is referred to as 1—reflectivity). Both OD and emissivity are data usually given in the industry to measure the reflectivity of a material.

### Example 1

The effect of evaporation of the protective layer under the controlled rate afforded by flash evaporation and its immediate deposition over aluminum on its resistance to corrosion was tested in several runs by metallizing a PET film in a conventional roll-to-roll vacuum metallization chamber. Using the equipment shown in FIG. 1, aluminum was deposited in each run as a layer 172 angstrom thick (corresponding to an optical density of about 2.5). A 0.2-micron layer of acrylate monomer was flash-evaporated in line and deposited over the aluminum layer, followed by curing with an electron-beam unit.

After the roll of aluminum barrier was removed from the vacuum chamber, it was unwound in air and subjected to a corrosion resistance test. The test consisted of placing the aluminum samples in a steam pressure cooker for various periods of time at about 40 degrees Centigrade and about 90 percent relative humidity and thereafter measuring their OD with a Cosar 70 CompuPlus densitometer. The same tests were carried out for comparison on aluminum films roll-coated with a layer of polymer at atmospheric pressure. The results of the tests are reported in Tables 3 and 4 below.

TABLE 3
Aluminum Film of Invention

| Time Exposure to Steam | Corrosion Condition as Measured by |
|---|---|
| at Atmospheric Pressure | Optical Density (OD)/Emissivity |
| 0 hrs | 3.23/0.05 |
| 0.25 hrs | 2.40/0.09 |
| 0.50 hrs | 1.42/0.19 |
| 0.75 hrs | 0.15/0.65 |
| 1.0 hrs | 0/0.89 (limit of detection) |

OD = 0, total corrosion
OD = 3.23, no corrosion

TABLE 4
Roll-Coated Aluminum Film*

| Time Exposure to Steam | Corrosion Condition as Measured by |
|---|---|
| at Atmospheric Pressure | Optical Density (OD)/Emissivity |
| 0 hrs | 4.00/0.055 |
| 0.25 hrs | 0/0.89 (limit of detection) |
| 0.5 hrs | Same as above |

OD = 0, total corrosion
OD = 4.0, no corrosion
*Dunmore Corporation's Reflective Aluminum Film

In general, when a polymeric film is metallized with aluminum or an aluminum alloy in vacuum, the roll of metallized film is removed from the vacuum chamber and processed in air in various ways, thereby allowing the natural formation of a protective aluminum oxide layer. During further processing and with the passage of time, however, the aluminum metal becomes exposed to some level of humidity and it forms a hydrated aluminum oxide, Al₂O₃. (H₂O)ₙ, which is structurally inferior to Al₂O₃. Therefore, corrosion of vapor-deposited aluminum is found, with some degree of attendant loss of reflectivity, even when the aluminum is deposited in the relatively moisture-free atmosphere of vacuum deposition.

Until recently, multilayer structures for various applications have been produced with little knowledge about the effects of hydrated aluminum oxides on the stability of the aluminum layer. What has not been fully appreciated is the fact that the substrate materials over which the aluminum is deposited (such as polymer films including polyester, nylon, polypropylene, polyethylene; and paper, textiles, foams, woven and non-woven materials; and others) retain a certain level of moisture even in vacuum. Therefore, when the aluminum, which is highly reactive in its metallic state, is wound into a multi-layer roll after deposition over the substrate in the vacuum chamber, it starts to react with such retained moisture in the roll before it is unwound in the air. Furthermore, if the roll is unwound in a humid environment (which is typical for most operations), the aluminum reacts with both oxygen and moisture. These conditions are an additional source of very undesirable formation of hydrated aluminum oxides.

Therefore, according to another aspect of the invention, the aluminum deposited in vacuum is preferably passivated upon deposition. The term “passivation” and related terminology are used in the art and herein to refer to the process of treating a metallic material, in particular aluminum and aluminum alloys, to alter their susceptibility to deterioration from exposure to environmental factors, especially moisture. With respect to this passivation step, the invention lies in the fact that the use of oxygen or, preferably, a plasma gas containing an oxygen-bearing molecule yields adequate in-line passivation of the metallic layer produced by vapor deposition during the course of manufacture of multi-layer structures. Such in-line passivation has been found to be particularly important in the manufacture of low-emissivity barriers for insulation applications where the retention of high reflectivity over time is critical for the continued performance of the product as an insulator.

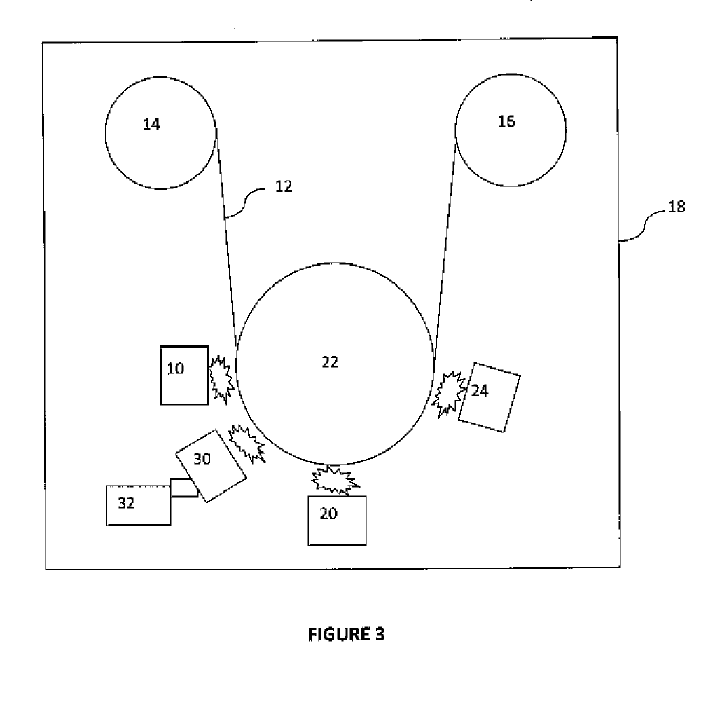

Thus, according to the invention, a gas containing an oxygen-bearing component is used to passivate the metal layer in line in the vacuum chamber, with or without a plasma. It was found that a controlled amount of oxygen or a plasma containing an oxygen-bearing gas can advantageously produce in-line oxidization of the metallic layer as necessary to ensure its subsequent long-term resistance to deterioration produced by moisture and other environmental factors. A low-voltage plasma treater 30 may be added to the process stream in the vacuum chamber 18, as illustrated in FIG. 3, and a source 32 of oxygen-bearing gas is added to the plasma gas (such as argon, helium or nitrogen) conventionally used in plasma units. The plasma treater 30 is positioned past the metal-vaporization unit 10 to treat the metallic layer deposited over the underlying web 12. The oxygen-bearing gases in the plasma gas result in the passivation of the metal layer in a continuous in-line sequence of operation. While not preferred, it was found that the use of oxygen alone would also provide a significant degree of passivation.

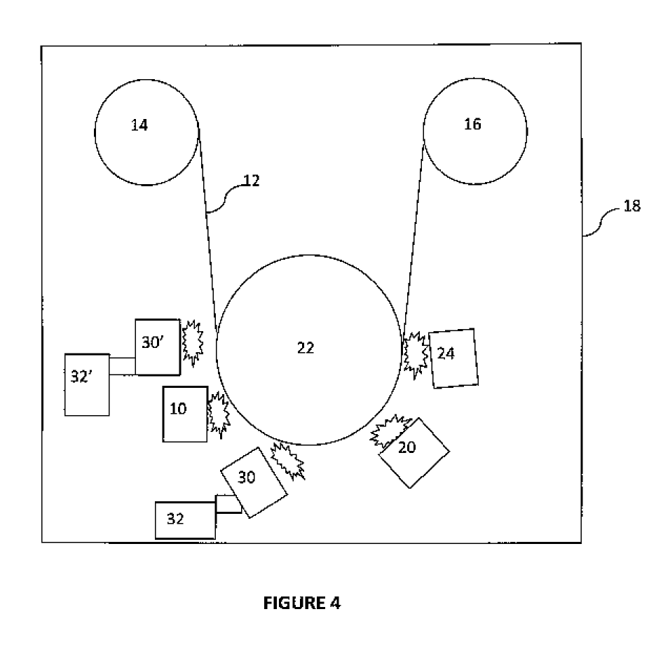

The use of the plasma treater 30 described above between the metal deposition and the polymer deposition steps, as shown in FIG. 3, produces passivation of the top side only of each metallic layer in the barrier structure. However, the same approach can be used advantageously to passivate also the underside of the metallic layer with an additional plasma treater 30′ and an associated oxygen-bearing source 32′ placed ahead of the metal-evaporation unit 10, as shown in FIG. 4. The presence of such a plasma gas promotes the immediate passivation of the underside of the metal layer as it is being deposited, further enhancing the anti-corrosion properties of the insulating barrier. Furthermore, the plasma treater 30′ can be used also to advantageously plasma treat the substrate 12 to improve adherence of the metal layer.

The following examples and test results illustrate the usefulness of the passivation steps of the invention. All percentages listed in the examples are based on volume.

### Example 2

The effect of oxygen plasma on resistance to corrosion was tested in several runs by metallizing a PET film in a conventional roll-to-roll vacuum metallization chamber. Using the equipment shown in FIG. 3, aluminum was deposited in each run as a layer about 25 nm thick (corresponding to an optical density of 3.1). After deposition, the surface of the aluminum film was exposed to an oxygen gas with and without plasma under different gas flow conditions, as shown in Table 5. The plasma was generated at a mid-frequency voltage of KHz and 2.5 KV. The aluminum film so treated was not coated with a protective polymeric layer. After the roll of film was removed from the vacuum chamber, it was unwound in air and subjected to a moisture resistance test that consisted of placing the metallized samples in a humidity chamber operating at 40° C. and 90% relative humidity for 65 hours. The samples then were placed on a light table and the corrosion condition of the aluminum layer was determined by visual inspection as a percentage of the light transmitted through the uncorroded aluminum. The results in Table 5 below show that untreated samples exhibited total corrosion, while the plasma treated samples showed great improvement.

TABLE 5

| | Corrosion Condition After 65 hrs at |
|---|---|
| Treatment Condition | 40 C/90% RH (Visual Observation) |
| No plasma* | Average corrosion condition after |
| Several samples from | tests = 0 |
| different metallization | |
| runs | |
| Plasma-treated samples | Average corrosion condition after |
| with 50 sccm of O₂/Ar | tests = 5 |
| (20%/80%) in the plasma | |
| reactor | |
| Plasma-treated samples | Average corrosion condition after |
| with 50 sccm of O₂/AR | tests = 8 |
| (50%/50%)in the plasma | |
| reactor | |
| Plasma-treated samples | Average corrosion condition after |
| with 50 sccm of O₂ only | tests = 10 |
| (100%)in the plasma | |
| reactor | |

10 = No detectable corrosion
0 = full corrosion - no aluminum remained on the substrate

### Example 3

In order to produce more quantitative results, PET film was metallised, as shown in the process of FIG. 4, and the aluminum metal was plasma treated after deposition, again with different gases, as indicated in Table 6 below. The degree of passivation was tested by dipping the treated film in de-ionized (DI) water for 90 seconds at 92° C., so as to corrode the aluminum metal by oxidation. The surface resistance of the film was then measured and compared to the resistance prior to the test as an indication of the degree of corrosion produced by the DI water (the Al₂O₃ produced by passivation being more resistant to corrosion than metallic aluminum and thus protected against increased resistivity and corresponding increased emissivity). The results show that higher oxygen contents during the treatment produced greater degrees of passivation in the aluminum layer.

TABLE 6

| | | Resistance of |
|---|---|---|
| | Initial Surface | Aluminum Layer After |
| | Resistance of | Dipping in DI water |
| Treatment Condition | Aluminum Layer | at 92 C for 90 sec. |
| Nitrogen Plasma | 9.0 ohm | 70.0 ohm |
| (100% N₂) - 50 sccm | | |
| Oxygen Plasma | 9.7 ohm | 10.5 ohm |
| (100% O₂) - 50 sccm | | |
| Dry Air Plasma | 8.0 ohm | 13.5 ohm |
| (100% air) - 50 sccm | | |
| Metallization with | 8.0 ohm | Non Conductive (fully |
| No Plasma | | corroded) |

These results demonstrate that passivation of the aluminum surface formed by flash evaporation immediately after deposition of the metal in vacuum prevents the formation of hydrated aluminum oxide and the related corrosion that normally occurs with aluminum film produced by conventional methods. Therefore, this in-line step of coating during the manufacture of aluminum films represents another significant advance in the art of reflective insulating films. The passivating step may be carried out using a plasma treatment or simply by exposure to a dry oxygen gas. Given the high-speed process conditions that are used for most metallizing operations, oxygen plasma is more practical, especially in cases where plasma pre-treatment of the underlying substrate is beneficial.

Inasmuch as flatness and smoothness of the metal layer deposited in vacuum are essential features for a shiny and highly reflective surface, it stands to reason that the final result also depends in part on the roughness of the substrate upon which the metal layer is deposited. For example, polyethylenes and lower-grade PETs normally have a surface that is materially rougher than polyesters, polyimids and higher-grade PETs. Therefore, when such rougher substrates are used, the reflectivity of the metallised film can be improved by depositing a leveling layer between the substrate and the metal layer. The same monomers used to protect metallic films, preferably acrylates, are also suitable for the purpose of forming a flat and smooth leveling layer over a relatively rough substrate surface, including paper and woven or non-woven materials.

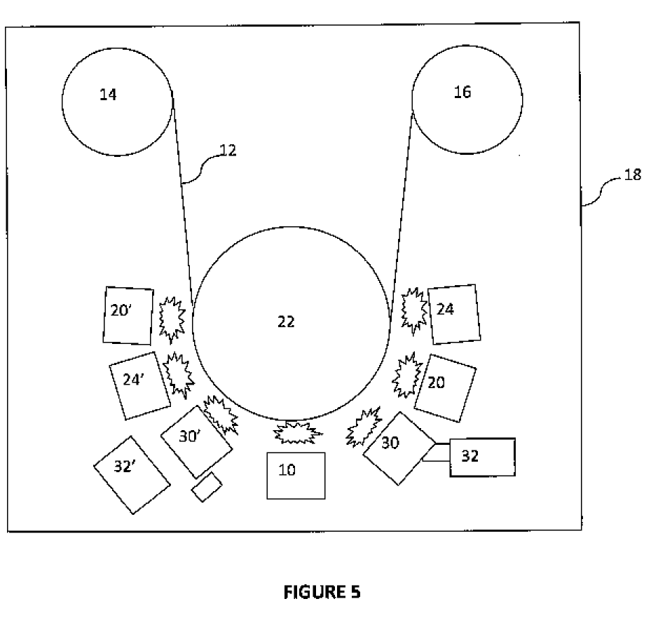

As illustrated in FIG. 5, this is accomplished with an additional monomer-evaporation unit 20′ and an associated radiation-curing unit 24′ placed upstream of the plasma treater 30′ and oxygen-bearing source 32′ (see FIG. 4), or, if these are not used, upstream of the metal-evaporation unit 10 (see FIG. 3). A very thin layer is deposited and cured in line prior to metallization, thereby providing an improved surface over which the metal layer can assume a nearly perfectly flat, highly reflective, surface. Table 7 below illustrates the improvements in emissivity obtained by depositing a thin acrylic layer over various substrates.

TABLE 7

| | Emissivity without | Emissivity with |
|---|---|---|
| Substrate | leveling | Leveling |
| Low-Grade PVC | 0.20-0.30 | 0.07-0.11 |
| Polyethylene | 0.18-0.20 | 0.09-0.13 |

This leveling feature of the invention has been found to be very valuable because it has enabled the production of reflective surfaces over substrates that had heretofore been impossible to metallize effectively (for example, commercial-grade PVC and PE).

The films produced according to the invention are suitable for lamination onto any material and/or structure simply by adding a layer of adhesive on the side of the substrate opposite the metal layer. Similarly, it is understood that the various functionalization steps described in the related cases (see U.S. Pat. No. 7,157,117, for instance), can be used to modify the outer protective layer to suit particular needs. For example, where the protective coat is expected to be touched by human hands during use, which may result in the deposition of oils that affect the integrity of the coating, an oleophobic and/or hydrophobic material (such as a fluorinated monomer) could be used for the deposition of the polymeric layer.

Thus, this invention provides a process for metallizing a variety of substrates to produce reflective films that can advantageously replace foils in many applications. Because of the much thinner aluminum layer used to produce the reflective surface and the single operation involved in manufacturing them, these vacuum deposited films are less expensive to produce than foils. Moreover, as explained above, films tend to self extinguish where foils tend to propagate flames. Films can be adhered to any backing required far any particular low-emissivity application, such as on plywood, insulation, ducting or tape for the building and construction industry, on pool covers, on space blankets, and on automotive components. Therefore, films are preferable to foils in the many applications for which foils have been used in the past.

With respect to vacuum-deposited films previously used in low-emissivity applications, the invention provides a product that absorbs less heat (because of the much thinner protective layer deposited in vacuum), is more durable (because of the passivation steps taken to protect the metal layer), and is more reflective (because of the leveling layer used to smooth the substrate). Therefore, the films of the invention represent a marked improvement over prior-art low-emissivity films.

The invention may be practiced over a variety of substrates including, without limitation, polymer films (such as, without limitation, polyesters, nylons, polyimids, polypropylenes, polyethylenes), paper, textiles, foams, woven and non-woven materials, and any roll materials. Similarly, the protective coatings may be radiation-curable monomers or oligomers (such as acrylates, epoxies, vinyls, and styrenics) or non-radiation curable materials such as solid polymer oligomers, ammelide, melam, ammeline, 2-ureidomelamine, cyanuric acid, melamine, melem, melon, and melamine salts.

Therefore, while the present invention has been shown and described herein in what is believed to be the most practical and preferred embodiments, it is recognized that departures can be made therefrom within the scope of the invention. For example, the invention has been described in terms of aluminum, but the various improvements described herein could be used with other reflective metals as well, such as tin, copper, zinc, silver, and metal oxides like ITO. Similarly, the invention has been described primarily in terms of flash-evaporation, which is preferred, but it is understood that any vacuum evaporation process that allows fine control of the thickness of deposition of the coating may be used to practice the invention. Thus, the invention is not to be limited to the details disclosed herein but is to be accorded the full scope of the claims so as to embrace any and all equivalent processes and products.

We claim:

1. A method for manufacturing a reflective multi-layer film comprising the following steps:
depositing a reflective metal layer on a moving web in a vacuum chamber;
evaporating a coating material in the vacuum chamber under a controlled rate of evaporation to produce a vapor; and
condensing the vapor to form a protective layer of said coating material over the metal layer;
wherein said coating material is deposited in a thickness known to produce at least approximately 75 percent reflectance in the 3 to 15 micron wavelength range of radiation impinging upon the multi-layer film.

2. The method of claim 1, wherein said reflective metal layer includes a metal selected from the group consisting of aluminum, tin, copper, zinc, silver, and metal oxides.

3. The method of claim 2, wherein said reflective metal layer is an aluminum layer.

4. The method of claim 1, further including the step of curing the protective layer.

5. The method of claim 4, wherein said evaporating step is carried out with flash evaporation and the coating material includes a radiation-curable material.

6. The method of claim 5, wherein said radiation-curable material includes a material selected from the group consisting of acrylates, epoxies, vinyls, and styrenics.

7. The method of claim 1, wherein said coating material includes a material selected from the group consisting of solid polymer oligomers, ammelide, melam, ammeline, 2-ureidomelamine, cyanuric acid, melamine, melem, melon, and melamine salts.

8. The method of claim 1, wherein said thickness of the coating material is less than approximately 0.50 microns.

9. The method of claim 1, further including the step of exposing said metal layer to a gas stream containing a passivating component after said depositing step.

10. The method of claim 9, wherein said gas stream containing a passivating component is a plasma gas containing oxygen-bearing molecules.

11. The method of claim 10, further including the step of injecting an other gas stream containing a passivating component over said web prior to the step of depositing the metal layer.

12. The method of claim 11, wherein said gas stream and other gas stream containing a passivating component are plasma gases containing oxygen-bearing molecules.

13. The method of claim 1, further including the following steps prior to said depositing step in the vacuum chamber:
flash evaporating a leveling monomer in the vacuum chamber to produce a vapor of said leveling monomer;
condensing the vapor of leveling monomer to form a layer of leveling monomer over the web; and
exposing said layer of leveling monomer to a curing unit to produce a polymeric leveling layer over the web.

14. The method of claim 13, further including the step of pre-treating said moving web with a plasma gas prior to said condensing step in the vacuum chamber.

15. The method of claim 1, further including the step of pre-treating said moving web with a plasma gas prior to said depositing step in the vacuum chamber.

16. The method of claim 1, further including the step of lining an object with said reflective multi-layer film to provide radiation insulation.

17. The method of claim 16, wherein said step of lining the object is carried out by adhering the reflective multi-layer film to the object.

18. A method for manufacturing a reflective multi-layer film over a moving web in a vacuum chamber comprising the following steps:
pre-treating the moving web with a plasma gas;
depositing a reflective aluminum layer on the moving web;
exposing the aluminum layer to a gas stream containing a passivating component;
flash evaporating a coating material in the vacuum chamber to produce a vapor;
condensing the vapor to form a protective layer of said coating material over the aluminum layer; and
curing the protective layer, thereby producing a reflective multi-layer film;
wherein said coating material is deposited in a thickness known to produce at least 75 percent reflectance in the 3 to 15 micron wavelength range of radiation impinging upon the multi-layer film.

19. The method of claim 1B, further including the following steps prior to said depositing step in the vacuum chamber:
flash evaporating a leveling monomer in the vacuum chamber to produce a vapor of said leveling monomer;
condensing the vapor of leveling monomer to form a layer of leveling monomer over the web; and
exposing said layer of leveling monomer to another curing unit to produce a polymeric leveling layer over the web.

20. The method of claim 18, further including the step of lining an object with said reflective multi-layer film to provide radiation insulation.

21. The method of claim 19, wherein said step of lining the object is carried out by adhering the reflective multi-layer film to the object.

22. An object insulated according to the method of claim 16.

23. An object insulated according to the method of claim 17.

24. An object insulated according to the method of claim 20.

25. An object insulated according to the method of claim 21.
